(19) United States
(12) Patent Application Publication
(10) Pub. No.: US 2024/0379643 A1
(43) Pub. Date: Nov. 14, 2024

(54) OPTICAL MODULE

(71) Applicant: InnoLight Technology (Suzhou) Ltd., Suzhou , Jiangsu (CN)

(72) Inventors: Zhen-Zhong WANG, Suzhou City , Jiangsu Province (CN); Shuai WANG, Suzhou City , Jiangsu Province (CN)

(21) Appl. No.: 18/684,653

(22) PCT Filed: Jun. 23, 2022
(86) PCT No.: PCT/CN2022/100795

§ 371 Date: Feb. 16, 2024

(30) Foreign Application Priority Data
Aug. 25, 2021 (CN) 202110983842.3

(51) Int. Cl. H01L 25/16; H01L 23/15; H01L 23/367

(52) U.S. Cl. CPC H01L 25/167; H01L 23/15; H01L 23/367

(57) ABSTRACT

An optical module (100, 200, 300), comprising a housing (11, 21, 31) as well as a circuit board (12, 22, 32), a digital signal processing chip (13, 23, 33), a substrate (14, 24, 34) and an optoelectronic chip (15, 25, 35) which are located within the housing (11, 21, 31). The circuit board (12, 22, 32) is provided with, in the thickness direction, a first surface (121, 221, 321) and a second surface (122, 222, 322) which are disposed opposite to one another. The digital signal processing chip (13, 23, 33) is electrically connected to a signal line (1201, 2201) of the circuit board (12, 22, 32) at the first surface (121, 221, 321). The substrate (14, 24, 34) is provided with a third surface (142, 242) and a fourth surface (141, 241) which are disposed opposite to one another. The optoelectronic chip (15, 25, 35) is electrically connected to a signal line (1401, 2401) of the substrate (14, 24, 34). The signal line (1201, 2201) of the circuit board (12, 22, 32) is provided with a first electrical connection point formed on the first surface (121, 221, 321), and the signal line (1401, 2401) of the substrate (14, 24, 34) is provided with a second electrical connection point formed on the third surface (142, 242), the first electrical connection point being electrically connected to the second electrical connection point. In this way, the signal line (1401, 2401) of the substrate (14, 24, 34) is inversely connected to the signal line (1201, 2201) of the circuit board (12, 22, 32) by means of the second electrical connection point. Compared with conventional connection means of gold wire bonding, the bandwidth between the digital signal processing chip (13, 23, 33) and the optoelectronic chip (15, 25, 35) may be greatly improved.

### CROSS-REFERENCE TO RELATED PATENT APPLICATION

This is the U.S. national phase application of International Application PCT/CN2022/100795, filed on Jun. 23, 2022, which international application was published on Mar. 2, 2023, as International Publication No. WO 2023/024682. The international application claims priority to China Patent Application No. 202110983842.3, filed on Aug. 25, 2021, in the People's Republic of China. The contents of which are incorporated herein by reference in their entireties.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a technical field of manufacturing optical communication components, and more particularly to an optical module.

### BACKGROUND OF THE DISCLOSURE

Optical communication technology, boasting advantages such as high bandwidth and low loss, is a key member in the field of communication. The optical module, responsible for optical-electrical conversion, is a core device in optical communication. In commonly used optical module technology, as shown in FIG. 1, a digital signal processing (DSP) chip 43 is loaded on a circuit board 42. A signal layer of a circuit board 42 is electrically connected to a substrate 44 that carries an optoelectronic chip 45, via a gold wire 40, so as to facilitate signal transmission between the DSP chip 43 and the optoelectronic chip 45. In such a setup, the conventional gold wire bonding process between the circuit board 42 and the substrate 44 limits the increase in bandwidth, which makes it difficult to meet the growing bandwidth requirements between the DSP chip 43 and the optoelectronic chip 45.

### SUMMARY OF THE DISCLOSURE

### Technical Problem

In order to solve the problems existing in conventional techniques, the purpose of the present disclosure is to provide an optical module.

### Solution of the Problem

### Technical Solution

In order to achieve the above object of the present disclosure, one embodiment provides an optical module, including a housing, a circuit board, a digital signal processing chip, a substrate and an optoelectronic chip located in the housing;
the circuit board being provided with, in a thickness direction, a first surface and a second surface which are disposed opposite to one another; the digital signal processing chip being electrically connected to a signal line of the circuit board at the first surface;
the substrate being provided with a third surface and a fourth surface which are disposed opposite to one another; the optoelectronic chip being electrically connected to a signal line of the substrate;
the circuit board and the substrate are stacked in the thickness direction, the first surface and the third surface face and abut against one another, the signal line of the circuit board is provided with a first electrical connection point formed on the first surface, the signal line of the substrate is provided with a second electrical connection point formed on the third surface, and the first electrical connection point is electrically connected to the second electrical connection point.

Preferably, the signal line of the substrate has a first end formed on the third surface, and the optoelectronic chip is electrically connected to the first end through a gold wire.

Preferably, the substrate is a ceramic substrate, and the optoelectronic chip is installed on the third surface of the ceramic substrate.

Preferably, the fourth surface and the housing are thermally connected through a second thermal conductor, and the second thermal conductor has a convex portion protruding and extending along the thickness direction of the circuit board toward the circuit board, and the convex portion is fixedly connected to the circuit board.

Preferably, the substrate includes:
a heat-insulating substrate, the second electrical connection point being located on a surface of the heat-insulating substrate; and,
a ceramic substrate, the optoelectronic chip being installed on the surface of the ceramic substrate, and the ceramic substrate and the circuit board being thermally isolated by the heat-insulating substrate.

Preferably, the optical module further includes a cooler, and a side of the ceramic substrate facing away from the optoelectronic chip is mounted on the cooler.

Preferably, the substrate includes:
a soldering plate portion overlapping the circuit board in the thickness direction; and,
an extension plate portion protruding from the circuit board, and the extension plate portion being supported by and fixed to the cooler through the ceramic substrate;
the optical module further including a heat-insulating support plate, and the soldering plate portion being supported by and fixed to the cooler through the heat-insulating support plate; the heat-insulating support plate and the welding plate part being arranged separately or integrally to form a protruding structure in the thickness direction of the heat-insulating substrate.

Preferably, the ceramic substrate is provided as an aluminum nitride substrate, and the heat-insulating support plate and the heat-insulating substrate are respectively provided as glass substrates having a thermal conductivity lower than a thermal conductivity of the aluminum nitride substrate.

Preferably, the ceramic substrate, the heat-insulating substrate and the circuit board are sequentially stacked in the thickness direction;
a top surface of the ceramic substrate and a top surface of the heat-insulating substrate jointly constitute the third surface, the optoelectronic chip is installed on the top surface of the ceramic substrate, and the first end is formed on the top surface of the heat-insulating substrate.

Preferably, the top surface of the optoelectronic chip is level with the top surface of the heat-insulating substrate.

Preferably, the top surface of the heat-insulating substrate has a reference ground line and a signal line, and the bottom surface of the heat-insulating substrate has a reference ground line.

Preferably, a bottom surface of the digital signal processing chip is mounted on the first surface, and a top surface thereof is thermally connected to the housing through a first thermal conductor.

In order to achieve the above object of the present disclosure, one embodiment provides an optical module, including a housing, a circuit board, a digital signal processing chip, a substrate and an optoelectronic chip located in the housing;
the optoelectronic chip being installed on the substrate and electrically connected to a signal line of the substrate; the digital signal processing chip being installed on the circuit board;
wherein the digital signal processing chip and the signal line of the substrate are on a same side of the circuit board, the digital signal processing chip is electrically connected to the signal line of the circuit board, and the signal line of the substrate and a signal line of the circuit board are structurally interconnected through an electrical connection point.

Preferably, the substrate includes a ceramic substrate, the optoelectronic chip is installed on a surface of the ceramic substrate and is located on a same side of the ceramic substrate as the circuit board;
the optical module further comprises a cooler, and a side of the ceramic substrate facing away from the optoelectronic chip is mounted on the cooler.

### Beneficial Effect of the Present Disclosure

### Beneficial Effect

Compared with the conventional techniques, the technical effect of the present disclosure is that: the signal line of the substrate is connected to the signal line of the circuit board in a flip-chip manner through the second electrical connection point, and the signal line of the substrate and the digital signal processing chip are electrically connected to the signal line of the circuit board on the same side of the circuit board (that is, the side where the first surface is located) in the thickness direction. In this way, compared with the conventional connection method of the gold wire bonding manner in conventional techniques, the bandwidth between the digital signal processing chip and the optoelectronic chip can be greatly increased.

### BRIEF DESCRIPTION OF THE DRAWINGS

### Description of the Drawings

FIG. 1 is a schematic structural diagram of an optical module used in related techniques;

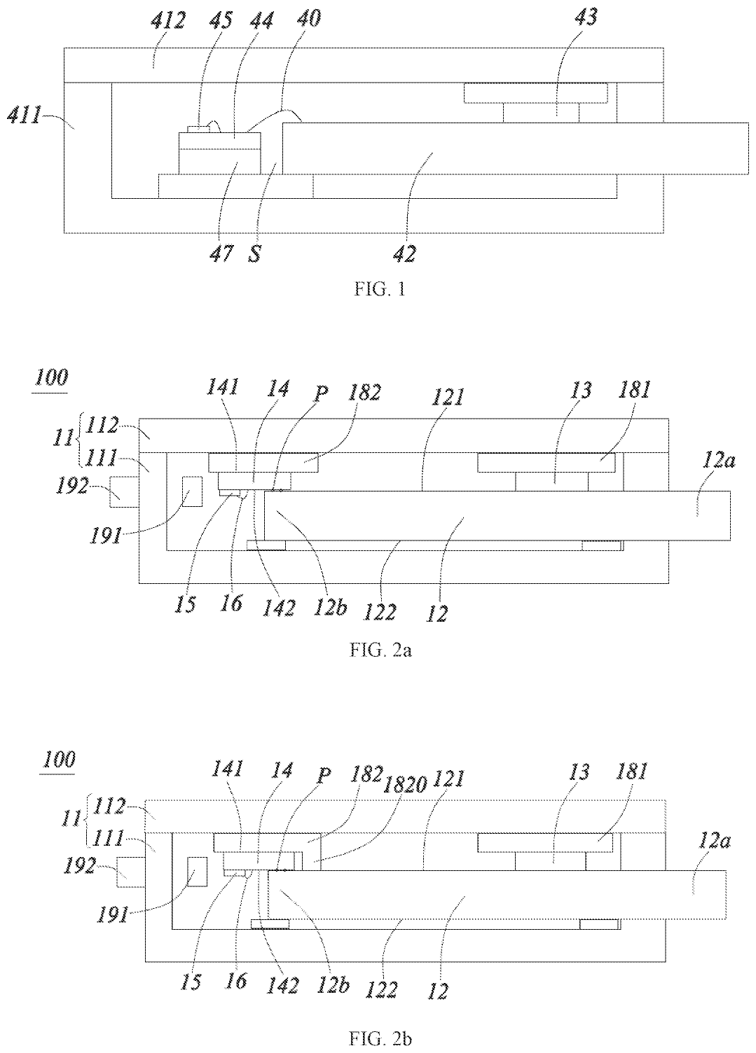

FIG. 2a is a schematic structural diagram of the optical module according to Embodiment 1 of the present disclosure, and a view angle schematically shown in FIG. 2a is a side view angle perpendicular to a thickness direction of the circuit board;

FIG. 2b is a schematic structural diagram of an optical module of a simple modified embodiment of Embodiment 1 of FIG. 2a;

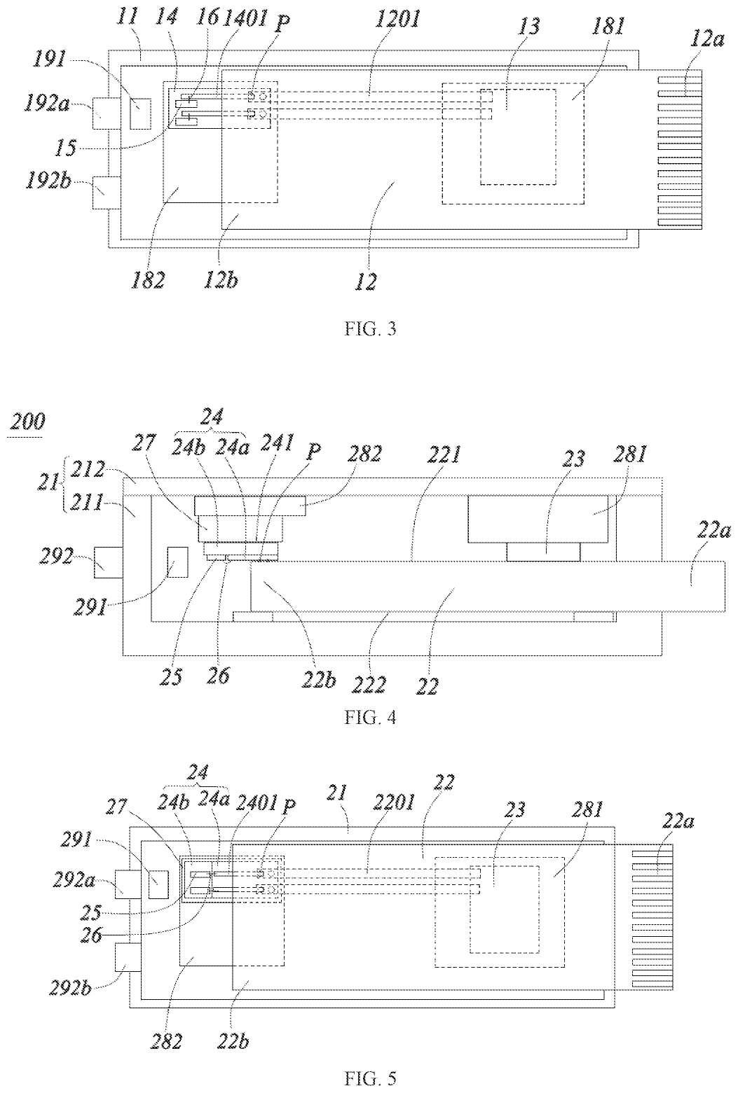

FIG. 3 is a partial structural perspective view of the optical module in FIG. 2a from a top view angle parallel to the thickness direction of the circuit board, in which a main outline of a component in perspective is depicted with broken lines;

FIG. 4 is a schematic structural diagram of an optical module according to Embodiment 2 of the present disclosure, in which a viewing angle schematically shown in this figure is a side viewing angle that is perpendicular to the thickness direction of the circuit board;

FIG. 5 is a partial structural perspective view of the optical module in FIG. 4 from a top view angle parallel to the thickness direction of the circuit board, in which a main outline of a component in perspective is depicted with broken lines;

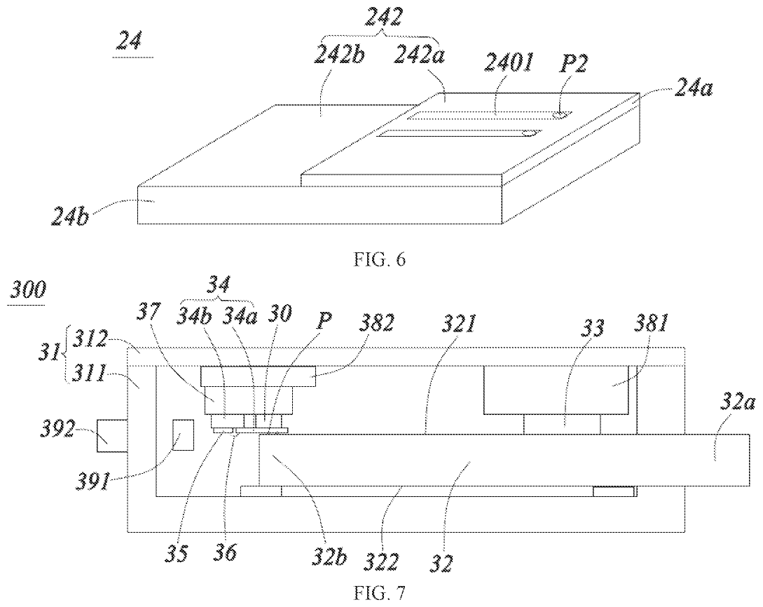

FIG. 6 is a schematic structural diagram of the substrate in FIG. 4;

FIG. 7 is a schematic structural diagram of an optical module according to Embodiment 3 of the present disclosure, in which a viewing angle schematically shown in this figure is a side viewing angle that is perpendicular to the thickness direction of the circuit board;

### REFERENCE NUMERALS

100, 200, 300, optical module; 11, 21, 31, housing; 111, 211, 311, 411, first housing; 112, 212, 312, 412, second housing; 12, 22, 32, 42, circuit board; 1201, 2201, signal lines of the circuit board; 121, 221, 321, first surface; 122, 222, 322, second surface; 12a, 22a, 32a, electrical connector end; 12b, 22b, 32b, optoelectronic mounting end; 13, 23, 33, 43, digital signal processing chip; 14, 24, 34, 44, substrate; 141, 241, fourth surface; 142, 242, third surface; 1401, 2401, signal line of substrate; 24a, 34a, heat-insulating substrate; 24b, 34b, ceramic substrate; 15, 25, 35, 45, optoelectronic chip; 16, 26, 36, gold wire; 40, gold wire; 27, 37, 47, semiconductor cooler; 181, 281, 381; first thermal conductor; 182, 282, 382, second thermal conductor; 191, 291, 391, optical element; 192, 292, 392, 192a, 192b, 292a, 292b, optical interface.

### DETAILED DESCRIPTION OF THE EXEMPLARY EMBODIMENTS

### The Exemplary Embodiments of the Present Disclosure

The present application will be described in detail below with reference to the specific embodiments shown in the accompanying drawings. However, these embodiments do not limit this application, and any structural, method, or functional changes made by those of ordinary skill in the art based on these embodiments are included in the protection scope of this application.

### Embodiment 1

Referring to FIGS. 2a and 3, the present embodiment provides an optical module 100, which includes a housing 11, a circuit board 12, a digital signal processing chip 13, a substrate 14 and an optoelectronic chip 15.

The housing 11 is generally in a shape of a hollow box, and the circuit board 12, the digital signal processing chip 13, the substrate 14 and the optoelectronic chip 15 are arranged in the housing 11. Specifically, the housing 11 includes a first housing 111 and a second housing 112, in which: the first housing 111 has four side walls and end walls respectively connected to the side walls; the second housing 112 is arranged substantially opposite to the end walls, and is assembled and connected to the four side walls through screws, buckles, and the like. The first housing 111 and the second housing 112 are assembled and connected to jointly form an accommodation cavity in the housing 11, and the circuit board 12, the digital signal processing chip 13, the substrate 14 and the optoelectronic chip 15 are accommodated in the accommodation cavity.

The circuit board 12 can be specifically provided as a rigid PCB (its full name in English being printed circuit board, or PCB for short), in other embodiments, the circuit board 12 can also be other types of substrates, such as a silicon substrate, a flexible circuit board, or a hybrid substrate, the substrate 14 can be referred to as a first substrate, and the circuit board 12 can be referred to as a second substrate; the circuit board 12 has a first surface 121 and a second surface 122 arranged oppositely in a thickness direction, that is, the first surface 121 and the second surface 122 are arranged oppositely, and a distance there-between defines a thickness of the circuit board 12. It can be understood that a span of the circuit board 12 in a direction perpendicular to the thickness direction is greater than the thickness of the circuit board 12.

The circuit board 12 has a reference ground line and a signal line 1201 for signal transmission, the signal line 1201 is electrically connected to the digital signal processing chip 13 at the first surface 121, such that the signal transmission between the signal line 1201 of the circuit board 12 and the digital signal processing chip 13 is possible.

Similarly, the substrate 14 has a reference ground line and a signal line 1401 for signal transmission, the signal line 1401 is electrically connected to the optoelectronic chip 15, such that the signal transmission between the signal line 1401 of the optoelectronic chip 15 is possible.

In this embodiment, the signal line of the circuit board 12 and the signal line 1401 of the substrate 14 are electrically connected through an electrical connection point (indicated by point P in the figure). Specifically, the circuit board 12 and the substrate 14 are stacked in the thickness direction; the substrate 14 has a third surface 142 and a fourth surface 141 that are oppositely arranged in the thickness direction, the third surface 142 and the first surface 121 face and abut against one another, and the fourth surface 141 and the second surface 122 are opposite to one another; the signal line 1401 is provided with a second electrical connection point formed on the third surface 142; correspondingly, the signal line of the circuit board 12 has a first electrical connection point formed on the first surface 121; the first electrical connection point is electrically connected to the second electrical connection point, thereby achieving an electrical connection between the signal line 1201 of the circuit board 12 and the signal line 1401 of the substrate 14.

As mentioned, the first electrical connection point and the second electrical connection point are both provided as pad structures, and the two are connected by soldering. In other embodiments, the first electrical connection point and the second electrical connection point can be exposed copper structures, and the two are connected by a conductive adhesive bonding manner. It can be understood that in the assembled optical module 100, as shown in FIG. 2a, the first electrical connection point and the second electrical connection point are in a form of an integrated solder joint (or solder balls); in this way, that is, for one assembled optical module, a junction between the signal line 1201 of the circuit board 12 and the signal line 1401 of the substrate 14 is intuitively a solder joint (or a solder ball); that is, it can be considered that the first electrical connection point and the second electrical connection point do exist.

In the optical module 100 of the present embodiment, the signal line 1401 of the substrate 14 is connected to the signal line 1201 of the circuit board 12 in a form of flip-chip soldering (or flip-chip bonding) through the second electrical connection point, the signal line 1401 and the digital signal processing chip 13 are electrically connected to the signal line 1201 of the circuit board 12 on the same side in the thickness direction of the circuit board 12 (that is, the side where the first surface 121 is located); in this way, compared to the conventional connection method of gold wire bonding in the conventional techniques, a bandwidth between the digital signal processing chip 13 and the optoelectronic chip 15 can be greatly increased.

In this embodiment, the signal line 1201 of the circuit board 12 is formed on the first surface 121, a first end thereof is electrically connected to the digital signal processing chip 13, and a second end thereof is configured as the first electrical connection point.

Furthermore, in this embodiment, the circuit board 12 has an electrical connector end 12a and an optoelectronic installing end 12b arranged oppositely in a length direction, where the length direction is perpendicular to the thickness direction of the circuit board 12, in which: the optoelectronic installing end 12b is located in the housing 11, and the electrical connector end 12a extends out of the housing 11 along the length direction of the circuit board 12, and is used for electrically connecting to external devices of the optical module 100, and the electrical connector end 12a in an example of the drawings specifically adopts a gold finger structure. The optoelectronic installing end 12b can also be located at a position adjacent to the middle of the circuit board 12; in this case, the circuit board 12 can be provided with a notch or an accommodating opening to accommodate optoelectronic devices.

The first electrical connection point is disposed at the optoelectronic installing end 12b, and the digital signal processing chip 13 is disposed close to the electrical connector end 12a relative to the substrate 14, that is, a distance between the digital signal processing chip 13 and the electrical connector end 12a is less than a distance between the substrate 14 and the electrical connector end 12a. Naturally, this is only one example of the present disclosure, and a positional relationship between the first electrical connection point and the digital signal processing chip 13 in the length direction of the circuit board 12 is not limited thereto.

In this embodiment, a bottom surface of the digital signal processing chip 13 is a signal connection surface, which is mounted and fixed on the first surface 121 and electrically connected to the signal line 1201 of the circuit board 12 through soldering. A top surface of the digital signal processing chip 13 is thermally connected to the housing 11 through the first thermal conductor 181, and specifically in this embodiment, the second housing 112, the first thermal conductor 181 and the digital signal processing chip 13 are stacked sequentially in the thickness direction of the circuit board 12, such that heat generated by an operation of the digital signal processing chip 13 is transferred to the second housing 112 through the first thermal conductor 181 for heat dissipation.

In this context, the material of the first heat conductor 181 is set as copper, which can also be referred to as a heat sink. One side of the first thermal conductor 181 (an upper side in FIG. 2a) is thermally connected to the second housing 112 through a flexible thermal conductive medium such as a thermal glue or a thermal pad, or directly attached to the second housing 112 while omitting the flexible thermal conductive medium; similarly, another side of the first thermal conductor 181 (a lower side in FIG. 2a) is thermally connected to the top surface of the digital signal processing chip 13 through a flexible thermal conductive medium such as a thermal glue or a thermal pad, or is directly attached to the top surface of the digital signal processing chip 13 while omitting the flexible thermal conductive medium.

In this embodiment, the signal line 1401 of the substrate 14 is formed on the third surface 142 of the substrate 14. Specifically, as mentioned above, the second end of the signal line 1401 is formed on the third surface 142 of the substrate 14, which is configured as the second electrical connection point; in addition, the first end of the signal line 1401 is also formed on the third surface 142 of the substrate 14, which is electrically connected to the optoelectronic chip 15. In this way, both the optoelectronic chip 15 and the circuit board 12 are electrically connected to the signal line 1401 of the substrate 14 at the third surface 142, which is beneficial to increasing the bandwidth.

In this embodiment, the optoelectronic chip 15 is installed on the third surface 142 of the substrate 14. Specifically, the bottom surface of the optoelectronic chip 15 is mounted and fixed on the third surface 142 through welding or other methods, and is electrically connected to the reference ground line of the substrate 14; the top surface of the optoelectronic chip 15 is a signal connection surface, which is electrically connected to the first end of the signal line 1401 through a gold wire 16. In this way, the circuit board 12 and the optoelectronic chip 15 are located on the same side of the substrate 14 (that is, the side where the third surface 142 is located), which facilitates a compact structural layout and shortens a span of the gold wire 16 between the signal line 1401 and the optoelectronic chip 15. It should be noted that a size and a ratio of each component in the drawings may not match the actual product, and the illustration here is merely for the purpose of facilitating explanation.

Furthermore, a part of the substrate 14 overlaps with the optoelectronic installing end 12b, and for ease of description and understanding, said part is defined as an overlapping area of the substrate 14; the remaining part protrudes from the photoelectric mounting end 12b along the length direction of the circuit board 12 and away from the electrical connector end 12a, and this part is defined as a protruding area of the substrate 14 for ease of description and understanding. The second end of the signal line 1401 (that is, the second electrical connection point) is formed on the overlapping area of the substrate 14; the first end of the signal line 1401 is formed on the protruding area of the substrate 14, correspondingly, the optoelectronic chip 15 is installed on the protruding area of the substrate 14; the signal line 1401 extends from the second end thereof (that is, the second electrical connection point) along the length direction of the circuit board 12 to the first end of the signal line 1401.

In this embodiment, the substrate 14 is configured as a ceramic substrate with high thermal conductivity, for example, ceramic materials such as aluminum nitride or aluminum oxide can serve as an insulating substrate, and use copper foil to construct the reference ground line and the signal line on the insulating substrate. The optoelectronic chip 15 is installed on the ceramic substrate (that is, the substrate 14), in this way, the substrate 14 is used not only to electrically connect the optoelectronic chip 15 with the signal line 1201 of the circuit board 12, but also to fixedly support the optoelectronic chip 15; the ceramic material has a high thermal conductivity, which can facilitate rapid heat dissipation of the optoelectronic chip 15.

Furthermore, the fourth surface 141 of the substrate 14 and the housing 11 are thermally connected through the second thermal conductor 182. Specifically in this embodiment, the second housing 112, the second thermal conductor 182, the substrate 14 and the optoelectronic chip 15 are stacked in sequence, such that the heat generated by the operation of the optoelectronic chip 15 is transferred to the second housing 112 through the ceramic substrate and the second thermal conductor 182 for heat dissipation.

In this context, the material of the second heat conductor 182 is set as copper, which can also be referred to as a heat sink. One side of the second thermal conductor 182 (an upper side in FIG. 2a) is thermally connected to the second housing 112 through a flexible thermal conductive medium such as a thermal glue or a thermal pad, or is directly attached to the second housing 112 while omitting the flexible thermal conductive medium. Another side of the second thermal conductor 182 (a lower side in FIG. 2a) is thermally connected to the substrate 14 through a flexible thermal conductive medium such as a thermal glue or a thermal pad, or is directly attached to the fourth surface 141 of the substrate 14 while omitting the flexible thermal conductive medium.

As a modified embodiment of the embodiment in the drawings, a TEC (its full name in English being thermo electric cooler, or TEC for short) can be added between the second thermal conductor 182 and the fourth surface 141 of the substrate 14 to further assist in keeping an operating temperature of the optoelectronic chip 15 constant; alternatively, in another variant embodiment, a semiconductor cooler can be used to replace the second heat conductor 182 in the embodiment of the drawings. For these two variant embodiments using the semiconductor coolers, in the present disclosure, the signal line 1401 of the substrate 14 is connected to the signal line 1201 of the circuit board 12 in a flip-chip manner through the second electrical connection point, in this way, the bandwidth can be further increased compared to conventional techniques while taking into account the thermal crosstalk issues, for example, as shown by the conventional technique in FIG. 1, to ensure operation stability of the semiconductor cooler 47, or, due to process level reasons, the circuit board 42 will be separated from the semiconductor cooler 47 with a certain gap S, causing the need for the gold wire 40 between the substrate 44 and the circuit board 42 to span the gap S, which affects the bandwidth, and the present disclosure eliminates the influence of the gap S and can increase the bandwidth while taking into account the operation stability of the semiconductor cooler.

In addition, as a modified embodiment of the embodiment in FIG. 2a, as shown in FIG. 2b, the second thermal conductor 182 has a convex portion 1820 that protrudes toward the circuit board 12 along the thickness direction of the circuit board 12, and the convex portion 1820 and the substrate 14 are arranged side by side on the same side of the circuit board 12, and in this way, the second thermal conductor 182 is generally L-shaped. The protruding portion 1820 is fixed together with the first surface 121 of the circuit board 12, for example, specifically by pasting or other methods, in this way, it can not only strengthen efficacy of bonding and fixation, but also enhance a heat dissipation rate of the circuit board 12 through the second heat conductor 182.

Furthermore, the optical module 100 also has an optical element 191 located in the housing 11 and an optical interface 192 installed on a side wall of the housing 11. Positions of the optoelectronic chip 15, the optical element 191 and the optical interface 192 are corresponding to one another to construct a transmitting light path from the optoelectronic chip 15 to the optical interface 192 through the optical element 191, or to construct a receiving light path from the optical interface 192 to the optoelectronic chip 15 through the optical element 191.

Specifically, the optoelectronic chip 15 can be configured as a laser, after a light emitted therefrom passes through the optical element 191, the light is output through the optical interface 192a; at this time, the optical module 100 can also be provided with another optical interface 192b for receiving external lights. Alternatively, the optoelectronic chip 15 can be specifically configured as a photodetector, and external lights are received through the optical interface 192a and then transmitted to the photodetector after passing through the optical element 191; at this time, the optical module 100 can also be provided with another optical interface 192b to emit the lights. Naturally, these are merely two specific examples of the optoelectronic chip 15, and specific implementations thereof are not limited to lasers and photodetectors.

In summary, compared with common technology, the optical module 100 of this embodiment mainly has the following beneficial effects: the signal line 1401 of the substrate 14 is connected to the signal line 1201 of the circuit board 12 in the flip-chip manner through the second electrical connection point, the signal line 1401 and the digital signal processing chip 13 are electrically connected to the signal line 1201 of the circuit board 12 on the same side in the thickness direction of the circuit board 12 (that is, the side where the first surface 121 is located), in this way, compared with the conventional connection method of the gold wire bonding manner in the conventional techniques, the bandwidth between the digital signal processing chip 13 and the optoelectronic chip 15 can be greatly increased.

### Embodiment 2

Referring to FIGS. 4 to 6, the present embodiment provides an optical module 200, which includes a housing 21, a circuit board 22, a digital signal processing chip 23, a substrate 24 and an optoelectronic chip 25.

The housing 11 is generally in a shape of a hollow box, and the circuit board 22, the digital signal processing chip 23, the substrate 24 and the optoelectronic chip 25 are arranged in the housing 21. Specifically, the housing 21 includes a first housing 211 and a second housing 212, in which: the first housing 211 has four side walls and end walls respectively connected to the side walls; the second housing 212 is arranged substantially opposite to the end walls, and is assembled and connected to the four side walls through screws, buckles, and the like. The first housing 211 and the second housing 212 are assembled and connected to jointly form an accommodation cavity in the housing 21, and the circuit board 22, the digital signal processing chip 23, the substrate 24 and the optoelectronic chip 25 are accommodated in the accommodation cavity.

The circuit board 12 can be specifically provided as a rigid PCB (full name in English is printed circuit board, PCB for short); the circuit board 22 has a first surface 221 and a second surface 222 arranged oppositely in a thickness direction, that is, the first surface 221 and the second surface 222 are arranged oppositely and a distance there-between defines a thickness of the circuit board 22. It can be understood that a span of the circuit board 22 in a direction perpendicular to the thickness direction is greater than the thickness of the circuit board 22.

The circuit board 22 has a reference ground line and a signal line 2201 for signal transmission, the signal line 2201 is electrically connected to the digital signal processing chip 23 at the first surface 221, such that the signal transmission between the signal line 2201 of the circuit board 22 and the digital signal processing chip 23 is possible.

Similarly, the substrate 24 has a reference ground line and a signal line 2401 for signal transmission, the signal line 2401 is electrically connected to the optoelectronic chip 25, such that the signal transmission between the signal line 2401 of the optoelectronic chip 25 is possible.

In this embodiment, the signal line 2201 of the circuit board 22 and the signal line 2401 of the substrate 24 are electrically connected through an electrical connection point (indicated by point P in the figure). Specifically, the substrate 24 has a third surface 242 and a fourth surface 241 that are oppositely arranged in the thickness direction, and the signal line 1401 is provided with a second electrical connection point P2 formed on the third surface 242; correspondingly, the signal line 2201 of the circuit board 22 has a first electrical connection point formed on the first surface 221; the first electrical connection point is electrically connected to the second electrical connection point P2, thereby achieving an electrical connection between the signal line 2201 of the circuit board 22 and the signal line 2401 of the substrate 24.

On it, the first electrical connection point and the second electrical connection point are both provided as pad structures, and the two are connected by soldering. In other embodiments, the first electrical connection point and the second electrical connection point can be exposed copper structures, and the two are connected by a conductive adhesive bonding manner. It can be understood that in the assembled optical module 200, as shown in FIG. 4, the first electrical connection point and the second electrical connection point P2 are in a form of an integrated solder joint (or solder balls), in this way, that is, for one assembled optical module, a junction between the signal line 2201 of the circuit board 22 and the signal line 2401 of the substrate 24 is intuitively a solder joint (or a solder ball), that is, it can be considered that the first electrical connection point and the second electrical connection point P2 do exist.

In the optical module 200 of the present embodiment, the signal line 2401 of the substrate 24 is connected to the signal line 2201 of the circuit board 22 in a form of flip-chip soldering (or flip-chip bonding) through the second electrical connection point P2, the signal line 2401 and the digital signal processing chip 23 are electrically connected to the signal line 2201 of the circuit board 22 on the same side in the thickness direction of the circuit board 22 (that is, the side where the first surface 221 is located), in this way, compared to the conventional connection method of gold wire bonding in the conventional techniques, a bandwidth between the digital signal processing chip 23 and the optoelectronic chip 25 can be greatly increased.

In this embodiment, the signal line 2201 of the circuit board 22 is formed on the first surface 221, a first end thereof is electrically connected to the digital signal processing chip 23, and a second end thereof is configured as the first electrical connection point.

Furthermore, in this embodiment, the circuit board 22 has an electrical connector end 24a and an optoelectronic installing end 24b arranged oppositely in a length direction, where the length direction is perpendicular to the thickness direction of the circuit board 22, in which: the optoelectronic installing end 24b is located in the housing 21, and the electrical connector end 24a extends out of the housing 21 along the length direction of the circuit board 22, and is used for electrical connecting to external devices of the optical module 200, and the electrical connector end 24a in an example of the drawings specifically adopts a gold finger structure.

The first electrical connection point is disposed at the optoelectronic installing end 24b; and the digital signal processing chip 23 is disposed close to the electrical connector end 24a relative to the substrate 24, that is, a distance between the digital signal processing chip 23 and the electrical connector end 24a is less than a distance between the substrate 24 and the electrical connector end 24a. Assuredly, this is only an example of the present disclosure, and a positional relationship between the first electrical connection point and the digital signal processing chip 23 in the length direction of the circuit board 22 is not limited thereto.

In this embodiment, a bottom surface of the digital signal processing chip 23 is a signal connection surface, which is mounted and fixed on the first surface 221 and electrically connected to the signal line 2201 of the circuit board 22 through soldering. A top surface of the digital signal processing chip 23 is thermally connected to the housing 21 through the first thermal conductor 281, and specifically in this embodiment, the second housing 212, the first thermal conductor 281 and the digital signal processing chip 23 are stacked sequentially in the thickness direction of the circuit board 22, such that heat generated by an operation of the digital signal processing chip 23 is transferred to the second housing 212 through the first thermal conductor 281 for heat dissipation.

In this context, the material of the first heat conductor 281 is set as copper, which can also be referred to as a heat sink. One side of the first thermal conductor 281 (an upper side in FIG. 4) is thermally connected to the second housing 212 through a flexible thermal conductive medium such as a thermal glue or a thermal pad, or is directly attached to the second housing 212 while omitting the flexible thermal conductive medium; similarly, another side of the first thermal conductor 281 (a lower side in FIG. 4) is thermally connected to the top surface of the digital signal processing chip 23 through a flexible thermal conductive medium such as a thermal glue or a thermal pad, or is directly attached to the top surface of the digital signal processing chip 23 while omitting the flexible thermal conductive medium.

In this embodiment, the signal line 2401 has a first end formed on the third surface 242 of the substrate 24, and the first end is electrically connected to the optoelectronic chip 25 through a gold wire 26. In this way, combined with the above context, the second electrical connection point P2 and the first end of the signal line 2401 are both formed on the third surface 242 of the substrate 24, such that both the optoelectronic chip 25 and the circuit board 22 are electrically connected to the signal line 2401 of the substrate 24 at the third surface 242, which is beneficial to increasing the bandwidth. In the example of the attached figures, on the third surface 242, the signal line 2401 extends from the second electrical connection point P2 thereof along the length direction of the circuit board 22 to the first end of the signal line 2401.

In this embodiment, the substrate 24 includes a ceramic substrate 24b with high thermal conductivity and a heat-insulating substrate 24a with low thermal conductivity.

The heat-insulating substrate 24a can specifically be an insulating substrate constructed of a glass material, and the signal line 2401 is constructed of a copper foil on the insulating substrate. A top surface of the heat-insulating substrate 24a forms a portion 242a of the third surface 242 (for convenience of description, it will be named a second portion surface 242a hereinafter); the second electrical connection point P2 and the first end of the signal line 2401 are both located on the heat-insulating substrate 24a, that is, located on the second portion surface 242a. In this way, the heat-insulating substrate 24a serves as a substrate for high-frequency signal interconnection of the optoelectronic chip 25, the optoelectronic chip 25 and the circuit board 22 are both electrically connected to the signal lines 2401 of the substrate 24 at the second portion surface 242a to optimize the structural layout.

In this embodiment, the substrate 14 can be an insulating substrate constructed of ceramic materials such as aluminum nitride or aluminum oxide, and the optoelectronic chip 25 is installed on the ceramic substrate 24b. In this way, the ceramic substrate 24b is used to fixedly support the optoelectronic chip 25, and the ceramic material has a high thermal conductivity, which can facilitate rapid heat dissipation of the optoelectronic chip 25.

In addition, thermal isolation is achieved between any position of the ceramic substrate 24b and the circuit board 22 through the heat-insulating substrate 24a, in other words, the heat-insulating substrate 24a is located between the ceramic substrate 24b and the circuit board 22, and the ceramic substrate 24a has no direct contact with the circuit board 22. In this way, while serving as the substrate for high-frequency signal interconnection of the optoelectronic chip 25, based on the glass material of the heat-insulating substrate 24a has a lower thermal conductivity than the ceramic material, such that the heat-insulating substrate 24a can block the heat generated by the operation of the circuit board 22 from transferring to the ceramic substrate 24b, thereby preventing thermal crosstalk of the circuit board 22 from affecting temperature control of the optoelectronic chip 25.

In this embodiment, one side of the ceramic substrate 24b facing away from the optoelectronic chip 25 (an upper side shown in the example in the figures) is mounted on a surface of the semiconductor cooler 27, that is, the semiconductor cooler 27, the ceramic substrate 24b and the optoelectronic chip 25 are stacked in sequence, in this way, a heat transfer path is established from the optoelectronic chip 25 through the ceramic substrate 24b to the semiconductor cooler 27, the semiconductor cooler 27 is used to stabilize the operating temperature of the optoelectronic chip 25 and improve life and signal quality of the optoelectronic chip 25; at the same time, combined with the above context, thermal isolation is achieved between any position of the ceramic substrate 24b and the circuit board 22 through the thermal insulation substrate 24a, which can also prevent the heat generated by the operation of the circuit board 22 from being transferred to the semiconductor cooler 27, causing the thermal load of the semiconductor cooler 27 to be too large, the semiconductor cooler 27 is merely used for the temperature control of the optoelectronic chip 25, ensuring that the semiconductor cooler 27 has a lower power consumption, further improving the operating temperature stability, life and signal quality of the optoelectronic chip 25.

In this embodiment, the ceramic substrate 24b and the heat-insulating substrate 24a are stacked, and the ceramic substrate 24b is disposed on one side of the heat-insulating substrate 24a facing away from the circuit board 22 in the thickness direction, that is, the ceramic substrate 24b, the heat-insulating substrate 24a and the circuit board 22 are stacked sequentially in the thickness direction; and, in addition to the second portion surface 242a formed on the heat-insulating substrate 24a, the third surface 242 further includes a portion 242b formed on the top surface of the ceramic substrate 24b (for convenience of description, it will be named a first portion surface 242a hereinafter), that is to say, the top surface of the ceramic substrate 24b and the top surface of the heat-insulating substrate 24a jointly construct the third surface 242 of the substrate 24; in which, the optoelectronic chip 25 is installed on the first portion surface 242b. In this way, on the one hand, the optoelectronic chip 25 and the heat-insulating substrate 24a are arranged side by side on the same side of the ceramic substrate 24b, and a connection between the optoelectronic chip 25 and the signal line 2401 can be realized through the gold wire 26 that is extremely short, so as to further increase the bandwidth; on the other hand, the optoelectronic chip 25 and the circuit board 22 are both located on the same side of the substrate 24 facing away from the semiconductor cooler 27 (that is, the side where the third surface 242 is located), which further increases the bandwidth and takes into account the thermal crosstalk issues when compared to conventional technologies, for example, the conventional technology shown in FIG. 1. To ensure the working stability of the semiconductor cooler 47, it is necessary to separate the circuit board 42 and the semiconductor cooler 47 by a certain gap S, resulting in a need for the gold wire between the substrate 44 and the circuit board 42 to span the gap S, which affects the bandwidth, so that the present disclosure eliminates the gap S and can increase the bandwidth, while taking into account the operation stability of the semiconductor cooler.

In this embodiment, the top surface of the optoelectronic chip 25 is flush with the second surface 242a to further increase the bandwidth. At the same time, in this embodiment, the heat-insulating substrate 24a can also adopt a more optimal structure with GSG together with a back ground layer, that is, the top surface (i.e., the second portion surface 242a) of the heat-insulating substrate 24a is provided with a conductive layer including a reference ground line and a signal line 2401, a reference ground line is provided on a bottom surface of the heat-insulating substrate 24a (i.e., an upper side in FIG. 4, facing away from the circuit board 22), and such a structure can further increase the bandwidth.

Furthermore, regarding the installation and connection between the optoelectronic chip 25 and the substrate 24, the reference ground line of the substrate 24 is at least partially located on the first surface 242b, and the bottom surface of the optoelectronic chip 25 is mounted and fixed on the first portion surface 242b of the third surface 242 by soldering or other methods, and is electrically connected to the reference ground line of the substrate 24; the top surface of the optoelectronic chip 25 is a signal connection surface, which is electrically connected to the first end of the signal line 2401 through the gold wire 26. In this way, it is conducive to the compactness of the structural layout.

Furthermore, the semiconductor cooler 27 and the housing 21 are thermally connected through a second thermal conductor 282. Specifically in this embodiment, the second housing 212, the second thermal conductor 282, the substrate 24 and the optoelectronic chip 25 are stacked in sequence, such that the thermal conduction is carried out through the second thermal conductor 282, which is beneficial to reducing the power consumption of the semiconductor cooler 27 and keeping the operating temperature of the optoelectronic chip 25 constant.

In this context, the material of the second heat conductor 282 is set as copper, which can also be referred to as a heat sink. One side of the second thermal conductor 282 (an upper side in FIG. 4) is thermally connected to the second housing 212 through a flexible thermal conductive medium such as a thermal glue or a thermal pad, or is directly attached to the second housing 212 while omitting the flexible thermal conductive medium. Another side of the second thermal conductor 282 (a lower side in FIG. 4) is thermally connected to the semiconductor cooler 27 through a flexible thermal conductive medium such as a thermal glue or a thermal pad, or is directly attached to the semiconductor cooler 27 while omitting the flexible thermal conductive medium.

Furthermore, the optical module 200 also has an optical element 291 located in the housing 21 and an optical interface 292 installed on a side wall of the housing 21. Positions of the optoelectronic chip 25, the optical element 291 and the optical interface 292 are corresponding to one another to construct a transmitting light path from the optoelectronic chip 25 to the optical interface 292 through the optical element 291, or to construct a receiving light path from the optical interface 292 to the optoelectronic chip 25 through the optical element 291.

Specifically, the optoelectronic chip 25 can be configured as a laser, after a light emitted therefrom passes through the optical element 291, the light is output through the optical interface 292a; at this time, the optical module 200 can also be provided with another optical interface 292b for receiving external lights. Alternatively, the optoelectronic chip 25 can be specifically configured as a photodetector, and external lights are received through the optical interface 292a and then transmitted to the photodetector after passing through the optical element 191; at this time, the optical module 200 can also be provided with another optical interface 292b to emit the lights. Naturally, these are merely two specific examples of the optoelectronic chip 25, and specific implementations thereof are not limited to lasers and photodetectors.

In summary, compared with common technology, the optical module 200 of this embodiment mainly has the following beneficial effects: firstly, the signal line 2401 of the substrate 24 is connected to the signal line 2201 of the circuit board 22 in the flip-chip manner through the second electrical connection point, the signal line 2401 and the digital signal processing chip 23 are electrically connected to the signal line 1201 of the circuit board 12 on the same side in the thickness direction of the circuit board 12 (that is, the side where the first surface 221 is located), in this way, compared with the conventional connection method of the gold wire bonding in the conventional techniques, the bandwidth between the digital signal processing chip 13 and the optoelectronic chip 15 can be greatly increased; secondly, by further utilizing an arrangement of the semiconductor cooler 27, the ceramic substrate 24b and the heat-insulating substrate 24a, the operating temperature of the photovoltaic chip 25 can be maintained stably, the thermal crosstalk between the circuit board 22 and the semiconductor cooler 27 can be reduced, and the power consumption of the semiconductor cooler 27 can be reduced.

### Embodiment 3

Referring to FIG. 7, the present embodiment provides an optical module 300. The only difference between this embodiment and the foregoing example shown in figures of Embodiment 2 is that a positional relationship between the ceramic substrate 24b and the heat-insulating substrate 24a in Embodiment 2 is adjusted, and based on which a heat-insulating support plate 30 is further added. Only the difference and effects will be introduced hereinafter, and the remaining contents that are the same as those in Embodiment 2 will be omitted.

In the above-mentioned example of the figures of Embodiment 2, the fourth surface 241 is completely constructed of the surface of the ceramic substrate 24b (the upper surface of the example in the figure), that is, the entire side surface of the heat-insulating substrate 24a facing away from the circuit board 22 is attached to the surface of the ceramic substrate 24b (or in other words, covered by the ceramic substrate 24b). Different from this, in Embodiment 3, the fourth surface of the substrate 34 is constructed by the ceramic substrate 34b and the heat-insulating substrate 34a, that is, only a part of the surface (top surface in FIG. 7) of the heat-insulating substrate 34a facing away from the circuit board 32 in the example in the figures is attached to the surface of the ceramic substrate 34b (or, in other words, covered by the ceramic substrate 34b), and the remaining part is not covered by the ceramic substrate 34b and constitutes a part of the fourth surface of the substrate 34.

In detail, in this embodiment, the heat-insulating substrate 34a includes a soldering plate portion that overlaps the circuit board 32 in the thickness direction and an extension plate portion that protrudes from the circuit board 32.

In this context, the extension plate portion is supported and fixed on the semiconductor cooler 37 through the ceramic substrate 34b; and the extension plate portion is provided with the first end of the signal line of the substrate 34, and the first end is electrically connected to the photoelectric chip 35 fixed on the ceramic substrate 34b through a gold wire 36.

The soldering plate portion is supported and fixed on the semiconductor cooler 37 through the heat-insulating support plate 30, in which the heat-insulating support plate 30 can be made of glass or other materials with a low thermal conductivity relative to the ceramic substrate 34b; moreover, the soldering plate portion is provided with the second electrical connection point of the signal line of the substrate 34, and the second electrical connection point is connected to the first electrical connection point of the signal line of the circuit board 32 by soldering. In this way, based on the technical efficacy of the aforementioned Embodiment 2, this embodiment further increases a thermal impedance between the circuit board 32 and the semiconductor cooler 37 by adding the heat-insulating support plate 30, thereby further efficiently reducing thermal impact applied to the semiconductor cooler 37 by the circuit board 32, this ensures that the semiconductor cooler 37 has a lower power consumption, and efficiently keeps the operating temperature of the photoelectric chip 35 constant, thereby achieving an increase in the bandwidth.

In this context, the soldering plate portion and the heat-insulating support plate 30 can be provided separately; or they can also be provided integrally, for example, the soldering plate portion includes an insulating substrate made of a glass material, and the insulating substrate and the heat-insulating substrate 30 made of glass are integrally formed, in this way, the heat-insulating support plate 30 is equivalent to forming a protruding structure of the heat-insulating substrate 34a that protrudes away from the circuit board 32 in the thickness direction.

In this embodiment, the ceramic substrate 34b and the circuit board 32 are completely offset from each other, that is, there is no overlap between the two in the thickness direction of the circuit board 32, in this way, a greater thermal resistance between the circuit board 32 and the semiconductor cooler 37 can be ensured.

In this embodiment, the thickness of the heat-insulating support plate 30 is substantially consistent with the thickness of the ceramic substrate 34b.

As mentioned above, compared with the conventional techniques, the optical module 300 of the present embodiment, on the basis of having the technical effects of the aforementioned Embodiment 2, increases the thermal impedance between the circuit board 32 and the semiconductor cooler 37 by adding the heat-insulating support plate 30, thereby further efficiently reducing thermal impact applied to the semiconductor cooler 37 by the circuit board 32; this ensures that the semiconductor cooler 37 has a lower power consumption, and efficiently keeps the operating temperature of the photoelectric chip 35 constant, thereby achieving an increase in the bandwidth.

It should be understood that although this specification is described in terms of implementations, not each implementation only contains one independent technical solution, and description of the specification is only for the sake of clarity. Persons skilled in the art should take the specification as a whole and understand each individual solution. The technical solutions in the embodiments can also be appropriately combined to form other embodiments that can be understood by those skilled in the art.

The series of detailed descriptions listed above are only specific descriptions of feasible implementations of the present disclosure and are not intended to limit the scope of protection of the present disclosure. Any equivalent implementations or changes that do not depart from the technical spirit of the present disclosure should be included in the protection scope of the present disclosure.

What is claimed is:

1. An optical module, comprising a housing, and a circuit board, a digital signal processing chip, a substrate and an optoelectronic chip that are located within the housing;
the circuit board being provided with, in a thickness direction, a first surface and a second surface which are disposed opposite to one another; the digital signal processing chip being electrically connected to a signal line of the circuit board at the first surface;
the substrate having a third surface and a fourth surface which are disposed opposite to one another; the optoelectronic chip being electrically connected to a signal line of the substrate;
wherein, the circuit board and the substrate are stacked in the thickness direction, the first surface and the third surface face and abut against one another, the signal line of the circuit board has a first electrical connection point formed on the first surface, the signal line of the substrate has a second electrical connection point formed on the third surface, and the first electrical connection point is electrically connected to the second electrical connection point.

2. The optical module according to claim 1, wherein the signal line of the substrate has a first end formed on the third surface, and the optoelectronic chip is electrically connected to the first end through a gold wire.

3. The optical module according to claim 2, wherein the substrate is a ceramic substrate, and the optoelectronic chip is installed on the third surface of the ceramic substrate.

4. The optical module according to claim 3, wherein the fourth surface and the housing are thermally connected through a second thermal conductor, and the second thermal conductor has a convex portion protruding and extending toward the circuit board along the thickness direction of the circuit board, and the convex portion is fixedly connected to the circuit board.

5. The optical module according to claim 2, wherein the substrate includes:
a heat-insulating substrate, the second electrical connection point being located on a surface of the heat-insulating substrate; and,
a ceramic substrate, the optoelectronic chip being installed on the surface of the ceramic substrate, and the ceramic substrate and the circuit board being thermally isolated by the heat-insulating substrate.

6. The optical module according to claim 5, further comprising a cooler, and a side of the ceramic substrate facing away from the optoelectronic chip is mounted on the cooler.

7. The optical module according to claim 6, wherein the heat-insulating substrate includes:
a soldering plate portion overlapping the circuit board in the thickness direction; and,
an extension plate portion protruding from the circuit board, and the extension plate portion being supported by and fixed to the cooler through the ceramic substrate;
the optical module further including a heat-insulating support plate, and the soldering plate portion being supported by and fixed to the cooler through the heat-insulating support plate; the heat-insulating support plate and the welding plate part being arranged separately or integrally to form a protruding structure in the thickness direction of the heat-insulating substrate.

8. The optical module according to claim 7, wherein the ceramic substrate is provided as an aluminum nitride substrate, and the heat-insulating support plate and the heat-insulating substrate are respectively provided as glass substrates having a thermal conductivity lower than a thermal conductivity of the aluminum nitride substrate.

9. The optical module according to claim 5, wherein the ceramic substrate, the heat-insulating substrate and the circuit board are sequentially stacked in the thickness direction;
a top surface of the ceramic substrate and a top surface of the heat-insulating substrate jointly constitute the third surface, the optoelectronic chip is installed on the top surface of the ceramic substrate, and the first end is formed on the top surface of the heat-insulating substrate.

10. The optical module according to claim 9, wherein the top surface of the optoelectronic chip is level with the top surface of the heat-insulating substrate.

11. The optical module according to claim 9, wherein the top surface of the heat-insulating substrate has a reference ground line and a signal line, and a bottom surface of the heat-insulating substrate has a reference ground line.

12. The optical module according to claim 1, wherein a bottom surface of the digital signal processing chip is mounted on the first surface, and a top surface thereof is thermally connected to the housing through a first thermal conductor.

13. An optical module, comprising a housing, and a circuit board, a digital signal processing chip, a substrate and an optoelectronic chip that are located in the housing;
the optoelectronic chip being installed on the substrate and electrically connected to a signal line of the substrate; the digital signal processing chip being installed on the circuit board;
wherein the digital signal processing chip and the signal line of the substrate are on a same side of the circuit board, the digital signal processing chip is electrically connected to the signal line of the circuit board, and the signal line of the substrate and a signal line of the circuit board are structurally interconnected through an electrical connection point.

14. The optical module according to claim 13, wherein the substrate includes a ceramic substrate, the optoelectronic chip is installed on a surface of the ceramic substrate and is located on a same side of the ceramic substrate as the circuit board;
the optical module further comprises a cooler, and a side of the ceramic substrate facing away from the optoelectronic chip is mounted on the cooler.
